(19) United States
(12) Patent Application Publication
(10) Pub. No.: US 2014/0283905 A1
(43) Pub. Date: Sep. 25, 2014

(54) Solar Power Brick

(71) Applicant: Sunvalue Co., Ltd., Kaohsiung City (TW)

(72) Inventors: Sheng Tsai Tseng, Kaohsiung City (TW); Sheng Lan Tseng, Kaohsiung City (TW)

(73) Assignee: Sunvalue Co., Ltd., Kaohsiung City (TW)

(21) Appl. No.: 14/097,985

(22) Filed: Dec. 5, 2013

(30) Foreign Application Priority Data
Mar. 20, 2013 (TW) 102205102

(51) Int. Cl. H01L 31/052

(52) U.S. Cl. CPC H01L 31/0524
USPC 136/256; 136/259

(57) ABSTRACT

A solar power brick includes an optical guide layer, at least one solar cell, at least one electrical connection line and an outer frame. The optical guide layer and the solar cells are provided in the outer frame to combine as an integrated body. The optical guide layer is provided at the central part of the outer frame, and the solar cell is provided between the optical guide layer and the outer frame. The optical guide layer with optical refraction is used to direct the incident light onto the solar cells at the lateral sides to convert incident light into electricity for supplying the electricity to the external devices. The present invention is appropriate for generating electricity and possibly applied to the field which needs the built-in power supply, thereby increasing the optical illuminated area and the received amount of light, improving the overall generating efficiency.

### CROSS-REFERENCE TO RELATED APPLICATION

This application claims priority to Taiwanese patent application No. 102205102, filed on Mar. 20, 2013, which is incorporated herewith by reference.

### BACKGROUND OF THE INVENTION

1. Field of the Invention

The present invention generally relates to a solar power brick, and more specifically to a solar power brick having an optical guide layer for directing the incident light onto the solar cells at the lateral sides so as to generate electricity.

2. The Prior Arts

Recently, with increased worldwide environmental protection consciousness like carbon reduction, the solar generator using solar cells has become one of the most appropriate alternative energies in the upcoming future because of its low pollution. Many advanced countries and energy industries have employed all kinds of resources to develop new technologies so as to improve the yield of the solar cells. For now, the solar cells are gradually applied to commercial generators which are connected to the normal electric grid system with the help of official strategies and subsidies.

The solar generator has a simpler structure not like the traditional thermal power generators, which always need a huge combustion/turbine machine to burn petrochemical fuel to convert the chemical energy into mechanical energy and further generating electricity. Because of low cost and easy maintenance, the solar generator is potentially applicable to many home devices to implement the function of generating electricity, such as solar windows, which may replace conventional windows.

In the prior arts, the solar window module utilizing the solar cells for generation of electricity is commonly provided with the largest illuminated area to allow the incident light to almost directly and perpendicularly illuminate the solar cells, thereby increasing the whole generating efficiency. However, one of the major shortcomings in the prior arts is that the solar cell prevents the light from penetrating interior such that the appearance of the solar window module looks gray or dark, and the indoor environment provided with the solar windows is often lack of sufficient daylight. This leads to poor visual aesthetic and seriously affects the actual application. Therefore, it greatly needs a new solar power brick allowing appropriate amount of light to penetrate so as to overcome the poor appearance resulting from gray color or dark, thereby solving the issues in the prior arts.

### SUMMARY OF THE INVENTION

The primary objective of the present invention is to provide a solar power brick, including an optical guide layer, at least one solar cell, an outer frame and at least one electrical connection line. The optical guide layer is provided at a central part of the outer frame, and each solar cell is provided between the optical guide layer and the outer frame. The electrical connection line penetrates the outer frame such that one end of the electrical connection line is connected to the at least one solar cell, and another end of the electrical connection line is connected to the outside of the outer frame. Specifically, the optical guide layer directs the incident light onto the at least one solar cell at the lateral sides, which converts the light into electricity further supplied to the electrical devices at the outside of the outer frame through the electrical connection line.

The optical guide layer is made of a transparent material, which consists of glass, acrylic, polycarbonate (PC), polyethylene (PE), polypropylene (PP) polymethyl methacrylate (PMMA), or polyethylene terephthalate (PET). The solar cell consists of a single crystal silicon, a polycrystalline silicon, amorphous silicon (a-Si), microcrystalline silicon, gallium arsenide (GaAs), cadmium telluride (CdTe), copper indium gallium selenide (CIGS) or III-V element. The outer frame is formed of a tough, protective material such as metal and plastic.

Additionally, the solar power brick of the present invention further includes a reflective film, which is provided at one side of the optical guide layer and served as a non-illuminated face, such that the light illuminate the reflective film can not penetrate, thereby implementing the solar power brick with only one illuminated face. The reflective film is made of a reflective material, such as a white environmental endurance film, aluminum/tin foil in silver color, metal plate or reflective slab.

The solar power brick of the present invention is thus suitably utilized as an electrical power generator unit to output feasible electricity and possibly applied to the field, which needs the built-in power supply so as to increase the optical illuminated area and the received amount of light, improve the overall generating efficiency, and further specifically implement the purpose of environmental protection, power saving and carbon reduction.

### BRIEF DESCRIPTION OF THE DRAWINGS

The present invention can be understood in more detail by reading the subsequent detailed description in conjunction with the examples and references made to the accompanying drawings, wherein:

FIG. 1 is a front view showing a solar power brick according to one embodiment of the present invention;

FIG. 2 is a side view showing the solar power brick of the present invention; and

FIG. 3 is a side view showing a solar power brick according to another embodiment of the present invention.

### DETAILED DESCRIPTION OF THE PREFERRED EMBODIMENTS

The present invention may be embodied in various forms and the details of the preferred embodiments of the present invention will be described in the subsequent content with reference to the accompanying drawings. The drawings (not to scale) show and depict only the preferred embodiments of the invention and shall not be considered as limitations to the scope of the present invention. Modifications of the shape of the present invention shall too be considered to be within the spirit of the present invention.

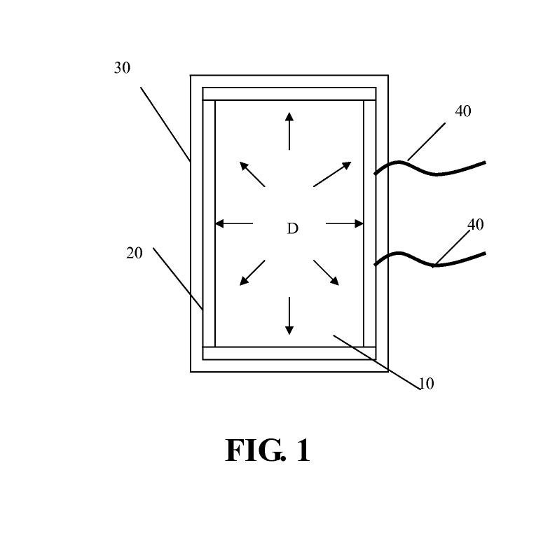

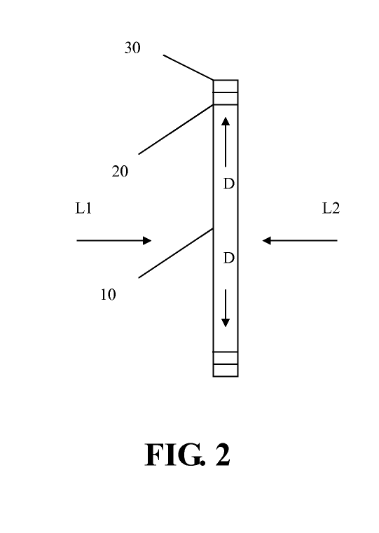

Please refer to FIGS. 1 and 2 illustrating the front and side views of a solar power brick according to one embodiment of the present invention, respectively. Specifically, the solar power brick of the present invention includes an optical guide layer 10, at least one solar cell 20, an outer frame 30 and at least one electrical connection line 40 for converting the incident light L1 and L2 from the left and right sides, respectively, into electricity through photoelectric transformation and further supplying the electricity to the external electrical devices (not shown) at the outside.

Preferably, the outer frame 30 has a framework structure providing protection and accommodating/fixing the optical guide layer 10, the solar cell 20 and the electrical connection line 40 so as to combine as an integrated body. The outer frame 30 is formed of metal, plastic or wood.

The optical guide layer 10 is provided at the central part of the outer frame 30, and each solar cell 20 is provided between the optical guide layer 10 and the outer frame 30. Additionally, the optical guide layer 10 is made of a transparent material like glass or plastic including acrylic, polycarbonate (PC), polyethylene (PE), polypropylene (PP), polymethyl methacrylate (PMMA), or polyethylene terephthalate (PET). The optical guide layer 10 further contains an optical guide material with the optical property of refraction such that the normal incident light L1 and L2 is directed to the lateral sides, shown by the guiding direction D in FIG. 1. It should be noted that the configuration of the solar cells 20 provided at four sides of the outer frame 30 in FIG. 1 is only an illustrative example, and thus not intended to limit the scope of the present invention. That is, each solar cell 20 can be provided at any side of the outer frame 30. Besides, the shape of the outer frame is a closed form, such as circle, triangle, rectangle, rhombus, polygon or curved shape.

The solar cell 20 possesses a function of photoelectric conversion and receives the light directed from the optical guide layer 10 to generate and output electricity. Specifically, the solar cell 20 consists of a single crystal silicon, a polycrystalline silicon, amorphous silicon (a-Si), microcrystalline silicon, gallium arsenide (GaAs), cadmium telluride (CdTe), copper indium gallium selenide (CIGS) or III-V element.

The electrical connection line 40 is electrically conductive and penetrates the outer frame 30. More specifically, one end of the electrical connection line 40 is connected to the solar cell 20, and another end is connected to the outside of the outer frame 30. As a result, the electricity generated by the solar cell 20 is transmitted to the outside of the outer frame 30 so as to supply the external electric devices (not shown) connected by the electrical connection line 40.

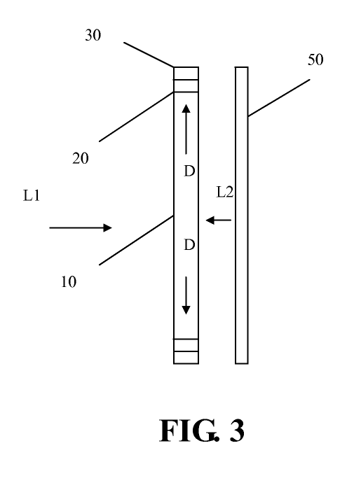

Since both sides of the solar power brick of the present invention are illuminated by the light from two opposite directions, the solar power brick is appropriate for a generating unit with high generating efficiency. Furthermore, FIG. 3 illustrates a side view of the solar power brick according to another embodiment of the present invention. As shown in FIG. 3, the solar power brick of the present embodiment has only one illuminated surface, and specifically includes the optical guide layer 10, the solar cell 20, the outer frame 30, the electrical connection line 40 and a reflective film 50. The optical guide layer 10, the at least one solar cell 20, the outer frame 30 and the electrical connection line 40 are similar to those of the above embodiment shown in FIGS. 1 and 2, and the detailed description is thus omitted. The reflective film 50 is provided at one side of the optical guide layer 10, like the left side in FIG. 3, such that the part of the light L1 penetrating the optical guide layer 10 is reflected by the reflective film 50 and then the reflected light is further directed to the solar cell 20 by the optical guide layer 10, thereby increasing the amount of generating power. Specifically, the reflective film 50 is a white environmental endurance film, aluminum/tin foil in silver color, metal plate or reflective slab.

From the above-mentioned, one aspect of the present invention is that the solar power brick has a simple structure and implements built-in electric source as a generating unit, which can supply other electric devices. Thus, the solar power brick of the present invention is suitable for the windows, walls, roofs of the traditional buildings or houses. At the same time, the solar power brick allows part of the light to penetrate and provides comfortable daylight environments. Particularly, the incident light is directed to the solar cells at the lateral sides because of the refraction of the solar power brick so as to increase the illuminated area and the amount of received light, thereby implementing environmental protection, power saving and carbon reduction.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A solar power brick for converting incident light into electricity to supply power for external devices, the solar power brick comprising:
an optical guide layer formed of a transparent material and containing an optical guide substance, wherein the optical guide layer has a property of optical refraction to direct the incident light onto lateral sides;
at least one solar cell for receiving the light from the optical guide layer and converting the received light into electricity;
at least one electrical connection line with electrical conduction, wherein one end of the electrical connection line is electrically connected to the solar cell; and
an outer frame for accommodating and fixing the optical guide layer, the at least one solar cell and the electrical connection line so as to combine as an integrated body, wherein the electrical connection line further penetrates the outer frame such that another end of the electrical connection line is connected to an outside of the outer frame for supplying the generated electricity to the outside, the optical guide layer is provided at a central part of the outer frame, and each solar cell is provided between the optical guide layer and the outer frame.

2. The solar power brick as claimed in claim 1, wherein the solar cell consists of a single crystal silicon, a polycrystalline silicon, amorphous silicon (a-Si), microcrystalline silicon, gallium arsenide (GaAs), cadmium telluride (CdTe), copper indium gallium selenide (CIGS) or III-V element.

3. The solar power brick as claimed in claim 1, wherein the transparent material of the optical guide layer consists of glass, acrylic, polycarbonate (PC), polyethylene (PE), polypropylene (PP), polymethyl methacrylate (PMMA), or polyethylene terephthalate (PET).

4. The solar power brick as claimed in claim 1, wherein the outer frame is formed of metal, plastic or wood.

5. The solar power brick as claimed in claim 1, wherein the outer frame has a closed form shape, a circle, a triangle, rectangle, a rhombus, a polygon or a curved shape.

6. The solar power brick as claimed in claim 1, further comprising a reflective film provided at a side of the optical guide layer for reflecting the light from a side opposite to the side of the optical guide layer.

7. The solar power brick as claimed in claim 6, wherein the reflective film is a white environmental endurance film, aluminum/tin foil in silver color, metal plate or reflective slab.
